(19) United States
(12) Patent Application Publication
(10) Pub. No.: US 2025/0079366 A1
(43) Pub. Date: Mar. 6, 2025

(54) SEMICONDUCTOR DEVICE WITH LAYERED DIELECTRIC

(71) Applicant: Micron Technology, Inc., Boise, ID (US)

(72) Inventors: Wei Zhou, Boise, ID (US); Bret K. Street, Meridian, ID (US); Akshay N. Singh, Boise, ID (US); Kunal R. Parekh, Boise, ID (US); Bharat Bhushan, Taichung (TW)

(21) Appl. No.: 18/788,588

(22) Filed: Jul. 30, 2024

Related U.S. Application Data
(60) Provisional application No. 63/536,611, filed on Sep. 5, 2023.

(51) Int. Cl. H01L 23/00; H01L 23/48; H01L 23/498; H01L 25/18; H10B 80/00

(52) U.S. Cl. CPC H01L 24/08; H01L 23/481; H01L 23/49894; H01L 24/80; H01L 24/96; H01L 24/97; H01L 25/18; H01L 2224/08145; H01L 2224/80895; H01L 2224/80896; H01L 2224/96; H01L 2224/97; H01L 2924/1431; H01L 2924/1436; H10B 80/00

(57) ABSTRACT

A semiconductor device assembly with layered dielectric is disclosed. The semiconductor device assembly includes a first semiconductor die and a second semiconductor die coupled with the first semiconductor die. The second semiconductor die is at least partially surrounded by a tensile dielectric and a compressive dielectric disposed at the first semiconductor die. The tensile dielectric is configured to experience tensile stress at an upper surface and compressive stress at a lower surface (e.g., the tensile dielectric will warp concave down). In contrast, the compressive dielectric is configured to experience compressive stress at an upper surface and tensile stress at a lower surface (e.g., the compressive dielectric will warp concave up). As a result, stress in the semiconductor device assembly can be reduced and overall yield can be improved.

### CROSS-REFERENCE TO RELATED APPLICATION(S)

The present application claims priority to U.S. Provisional Patent Application No. 63/536,611, filed Sep. 5, 2023, the disclosure of which is incorporated herein by reference in its entirety.

### TECHNICAL FIELD

The present disclosure generally relates to semiconductor device assemblies and more particularly relates to a semiconductor device with layered dielectric.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIGS. 2-7 illustrate simplified schematic cross-sectional views of a series of steps for fabricating semiconductor device assemblies in accordance with an embodiment of the present technology.

FIG. 8 illustrates a schematic view of a system that includes a semiconductor device assembly configured in accordance with an embodiment of the present technology.

FIG. 9 illustrates a method of fabricating a semiconductor device assembly in accordance with an embodiment of the present technology.

### DETAILED DESCRIPTION

Designers can utilize stacked semiconductor device assemblies to implement a greater number of circuit components within a device, thereby enabling the device to perform a greater number of operations per second, store greater amounts of data, or operate with a higher level of security. For example, a stacked semiconductor device can include multiple semiconductor dies assembled vertically into a package without increasing the footprint of the device. As performance requirements for semiconductor devices continue to increase, designers are tasked with implementing additional semiconductor dies within a single package while concurrently limiting package height to fit the spatial constraints of the devices in which they are implemented. Accordingly, semiconductor dies are often thinned to maximize the number of dies that can fit within a package. As dies become thinner, however, processing becomes increasingly challenging and yield decreases. For example, semiconductor devices can experience stress that can warp or fracture the semiconductor die. In some cases, this warpage can be caused by differences in material properties (e.g., thermal expansion coefficients) between various materials within the package (e.g., a mold resin encapsulating the dies and the dies themselves).

To address these drawbacks and others, various embodiments of the present technology provide semiconductor device assemblies that implement layers of dielectric material. The semiconductor device assembly includes a first semiconductor die and a second semiconductor die coupled with the first semiconductor die. The second semiconductor die is at least partially surrounded by a tensile dielectric and a compressive dielectric disposed at the first semiconductor die. The tensile dielectric is configured to experience tensile stress at an upper surface and compressive stress at a lower surface (e.g., the tensile dielectric will warp concave down). In contrast, the compressive dielectric is configured to experience compressive stress at an upper surface and tensile stress at a lower surface (e.g., the compressive dielectric will warp concave up). As a result, the tensile dielectric and the compressive dielectric can offset the stress in the semiconductor device assembly and improve yield.

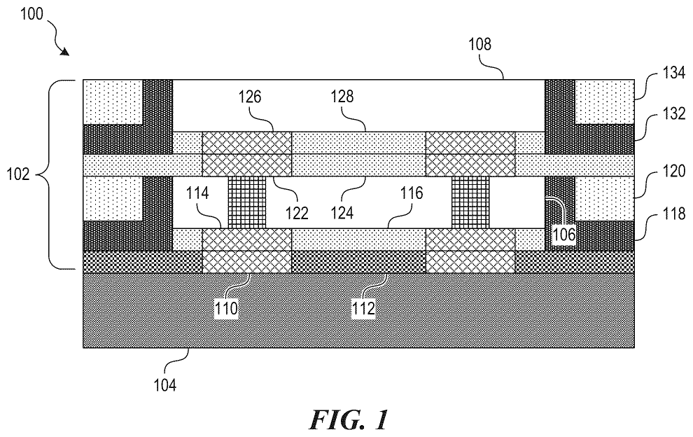

FIG. 1 illustrates a simplified schematic cross-sectional view of a semiconductor device assembly 100 that includes a stack of semiconductor dies 102 (e.g., memory dies) assembled onto a semiconductor die 104 (e.g., logic die). The semiconductor die 104 may be singulated from a wafer of semiconductor dies (e.g., logic dies) after the stack of semiconductor dies 102 is assembled onto the wafer of semiconductor dies. The semiconductor die 104 includes contact pads 110 and a dielectric material 112 (e.g., a dielectric block). In aspects, the dielectric material 112 extends entirely over the surface of the semiconductor die 104. As illustrated, the stack of semiconductor dies 102 includes a semiconductor die 106 and a semiconductor die 108. The semiconductor die 106 includes contact pads 114 and dielectric material 116 (e.g., a dielectric block) at a first side (e.g., an active side at which a metallization layer is disposed). The semiconductor die 106 can be coupled (e.g., hybrid bonded) with the semiconductor die 104 such that the contact pads 110 and the contact pads 114 form interconnects electrically coupling the dies, and the dielectric material 112 and the dielectric material 116 are directly bonded. As illustrated, the semiconductor die 104 has a larger footprint than the semiconductor die 106. As a result, the dielectric material 112 can extend beyond the dielectric material 116.

Dielectric sidewalls that include a dielectric material 118 and a dielectric material 120 can be disposed on the semiconductor die 104 (e.g., on the dielectric material 112) at least partially surrounding the semiconductor die 106. In some cases, the ratio of the dielectric material 118 to the dielectric material 120 can be 1:2, 1:1, 2:1, or any ration therebetween. The dielectric material 118 and the dielectric material 120 can include a tensile dielectric and a compressive dielectric. In aspects, a tensile dielectric can be configured to experience tensile stress at an upper surface and compressive stress at a lower surface. In this way, a tensile dielectric, when not influenced by other factors, can warp in a concave down shape. In contrast, a compressive dielectric can be configured to experience compressive stress at an upper surface and tensile stress at a lower surface. Thus, a compressive dielectric, when not influenced by other factors, can warp in a concave up shape. In some cases, the dielectric material 118 can include a tensile dielectric, and the dielectric material 120 can include the compressive dielectric. Alternatively, the dielectric material 118 can include a compressive dielectric, and the dielectric material 120 can include the tensile dielectric. In yet other aspects, the dielectric material 118 and the dielectric material 120 can both include a tensile dielectric or a compressive dielectric.

As illustrated, the dielectric material 118 is disposed on the semiconductor die 104. The dielectric material 118 can extend up an edge of the semiconductor die 106 extending between the first side at which contact pads 114 are disposed and a second side (e.g., an inactive side opposite the active side) at which contact pads 122 and dielectric material 124 (e.g., a dielectric block) are disposed. The dielectric material 120 can be disposed at the dielectric material 118. As illustrated, the dielectric material 118 or the dielectric material 120 can extend to an upper surface of the semiconductor die 106. The dielectric material 124 can extend across the second side of semiconductor die 106 and at least partially over the dielectric material 118 or the dielectric material 120. In this way, the dielectric material 124 can contact the dielectric material 118 or the dielectric material 120.

The semiconductor die 108 can be coupled (e.g., hybrid bonded) with the semiconductor die 106. The semiconductor die 108 can include a first side (e.g., an active side) at which contact pads 126 and dielectric material 128 (e.g., a dielectric block) are disposed. The contact pads 126 and the contact pads 122 can form metal-metal bonds to implement interconnects electrically coupling the semiconductor die 106 and the semiconductor die 108. Moreover, the dielectric material 124 and the dielectric material 128 can directly bond. In aspects, through-silicon vias (TSVs) 130 can extend between the contact pads 114 and the contact pads 122 on the semiconductor die 106. As a result, the semiconductor die 108 can be electrically coupled with the semiconductor die 104 using the TSVs 130.

Similar to the semiconductor die 106, dielectric sidewalls that include a dielectric material 132 and a dielectric material 134 can be disposed at the dielectric sidewall surrounding the semiconductor die 106 and at least partially surrounding the semiconductor die 108. As discussed, the dielectric material 124 can extend over the dielectric material 118 or the dielectric material 120. Accordingly, the dielectric material 132 or the dielectric material 134 can be disposed at the dielectric material 124, and the dielectric material 124 can separate the dielectric material 132 from the dielectric material 120. Similar to the dielectric material 118 and the dielectric material 120, the dielectric material 132 can include a first one of a tensile dielectric and a compressive dielectric, and the dielectric material 134 can include the other of the tensile dielectric and the compressive dielectric. Alternatively, the dielectric material 132 and the dielectric material 134 can both include a tensile dielectric or a compressive dielectric.

The dielectric material 132 can extend up an edge surface of the semiconductor die 108. The dielectric material 134 can be disposed at least partially on the dielectric material 132. As illustrated, the dielectric material 132 and the dielectric material 134 extend to an upper surface of the semiconductor die 108. Alternatively, the dielectric material 132 or the dielectric material 134 can extend over an upper surface of the semiconductor die 108. Although not illustrated, the semiconductor die 108 can include TSVs that extend to contact pads at the upper surface to enable probing or communication signaling through the contact pads.

Although the stack of semiconductor dies 102 is illustrated as two semiconductor dies, semiconductor die 106 and semiconductor die 108, other implementations are possible that include more or fewer semiconductor dies. Similarly, other implementations exist that include the stack of semiconductor dies 102 arranged differently. For example, the stack of semiconductor dies 102 could be replaced with a stack of semiconductor dies assembled in a back-to-front arrangement (e.g., instead of a front-to-back arrangement). Moreover, the stack of semiconductor dies 102 could be replaced with a single semiconductor die having a front side facing the semiconductor die 104 or a back side opposite the front side and facing the semiconductor die 104. Accordingly, the total number of semiconductor dies in the stack of semiconductor dies 102 could equal 2, 3, 4, 5, 6, 8, 10, 12, 14, 16, or any other number of semiconductor dies. Moreover, the dielectric material can be any appropriate dielectric material. For example, any of the dielectric materials can include silicon oxide, silicon nitride, silicon carbide, silicon carbon nitride, or any other dielectric material.

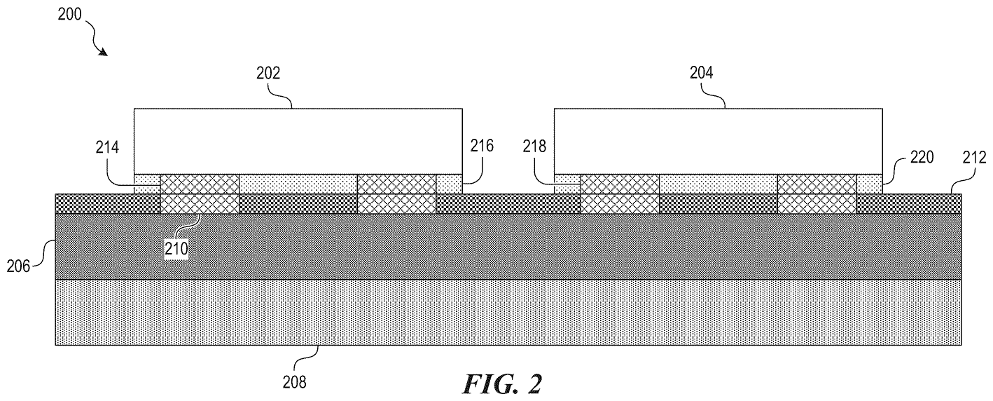

This disclosure now turns to a series of steps for fabricating semiconductor device assemblies in accordance with embodiments of the present technology. Specifically, FIGS. 2-7 illustrate simplified schematic cross-sectional views of a series of steps for fabricating semiconductor device assemblies in accordance with an embodiment of the present technology. The steps are illustrated with respect to a specific embodiment for ease of description. However, the steps described with respect to FIGS. 2-7 could be performed to fabricate semiconductor device assemblies in accordance with other embodiments.

Beginning with FIG. 2 at stage 200, a simplified schematic cross-sectional view of a semiconductor die 202 and a semiconductor die 204 coupled to a wafer of semiconductor dies 206 is illustrated. The wafer of semiconductor dies 206 can be adhered (e.g., through an adhesive or a dielectric material) to a carrier wafer 208 to support the semiconductor device assembly during processing. The wafer of semiconductor dies 206 includes multiple semiconductor dies (e.g., logic dies). The wafer of semiconductor dies 206 can have a first side (e.g., an active side) at which contact pads 210 and dielectric material 212 (e.g., a dielectric block) are disposed. In aspects, the dielectric material 212 can include any appropriate dielectric material, for example, silicon oxide, silicon nitride, silicon carbide, silicon carbon nitride, and so on. As illustrated, the dielectric material 212 can be disposed across the entire first side of the wafer of semiconductor dies 206.

The semiconductor die 202 can be coupled (e.g., chip-to-wafer hybrid bonded) with the wafer of semiconductor dies 206 at a first lateral location (e.g., a first semiconductor die of the wafer of semiconductor dies 206). The semiconductor die 202 can include contact pads 214 and a dielectric material 216 (e.g., a dielectric block of any dielectric material) disposed along a first side (e.g., active side) of the semiconductor die 202. The contact pads 214 can electrically couple with the contact pads 210 to form metal-metal interconnects. Moreover, the dielectric material 212 and the dielectric material 216 can directly bond. The semiconductor die 202 can have a greater thickness at stage 200 compared to the final semiconductor device assembly to enable the semiconductor die 202 to withstand processing (e.g., TSV deposition or bonding). For example, the semiconductor die 202 can have a thickness greater than 5 microns, 10 microns, 15 microns, 20 microns, 25 microns, and so on. The semiconductor die 204 can be similarly coupled (e.g., chip-to-wafer hybrid bonded) with the wafer of semiconductor dies 206 at a second lateral location (e.g., a second semiconductor die of the wafer of semiconductor dies 206) through the contact pads 218 and the dielectric material 220.

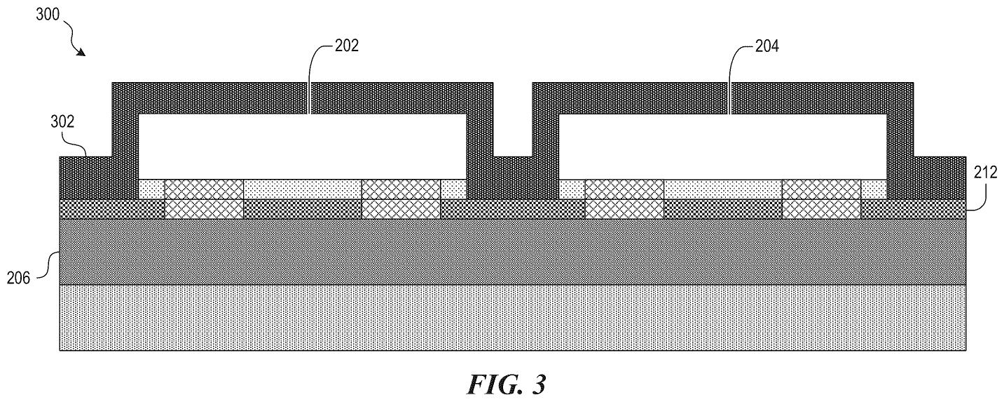

FIG. 3 illustrates a simplified schematic cross-sectional view of stage 300, where a dielectric material 302 is disposed at the wafer of semiconductor dies 206 and over the semiconductor die 202 and the semiconductor die 204. In aspects, the dielectric material 302 can be disposed at the wafer of semiconductor dies 206 exposed beyond the footprint of the semiconductor die 202 and the footprint of the semiconductor die 204 (e.g., between the semiconductor die 202 and the semiconductor die 204). The dielectric material 302 can be disposed through any appropriate technique, for example, chemical vapor deposition or physical vapor deposition. The dielectric material 302 can extend along the edge surfaces of the semiconductor die 202 and the edge surfaces of the semiconductor die 204. The dielectric material 302 can be disposed with a pattern conformal to the semiconductor die 202 and the semiconductor die 204.

The dielectric material 302 can include a tensile dielectric configured to experience tensile stress at an upper surface and compressive stress at a lower surface or a compressive dielectric configured to experience compressive stress at an upper surface and tensile stress at a lower surface. In aspects, the dielectric material 302 can be implemented as a tensile dielectric or a compressive dielectric based on the stress characteristics of the semiconductor device assembly before the dielectric material 302 is disposed.

For example, the semiconductor device assembly (e.g., the wafer of semiconductor dies 206) can be determined to experience tensile stress at an upper surface (e.g., at a dielectric material 212) and compressive stress at a lower surface (e.g., opposite the dielectric material 212). As a result, the semiconductor device assembly can warp concave down if not influenced by other factors. Alternatively, the semiconductor device assembly can be determined to experience compressive stress at an upper surface and tensile stress at a lower surface (e.g., the semiconductor device assembly will warp concave up). The dielectric material 302 can then be selected as a tensile dielectric or a compressive dielectric to counteract the stress at the semiconductor device assembly. For example, if the semiconductor device assembly is configured to experience tensile stress at an upper surface such that the semiconductor device assembly warps concave down, the dielectric material 302 can be selected as a compressive dielectric configured to warp concave up. Alternatively, if the semiconductor device assembly is configured to experience compressive stress at an upper surface such that the semiconductor device assembly warps concave up, the dielectric material 302 can be selected as a tensile dielectric configured to warp concave down.

In aspects, whether a dielectric material is tensile or compressive can be determined based on a number of factors. For example, different dielectric materials can be tensile or dielectric. Moreover, the techniques through which a dielectric material is deposited (e.g., deposition temperature) can affect the extent to which the dielectric material is tensile or compressive. In yet other aspects, the thickness of the dielectric material can affect the extent to which the dielectric material is tensile or compressive. For example, a thicker dielectric material can have a greater propensity (e.g., experience greater amounts of stress) to experience tensile or compressive stress. These aspects of the dielectric material 212 can similarly be determined based on stress characteristics of the semiconductor device assembly before the dielectric material 302 is disposed. The amount of tensile stress or compressive stress configured to be experienced by the upper surface of the semiconductor device assembly can be determined, and dielectric material 302 can have properties that counteract that stress. For example, when a higher stress is configured to be experienced by the semiconductor device assembly, the dielectric material 212 can be implemented with a greater thickness, as a material configured to experience higher amounts of stress, or through a deposition technique that causes the dielectric material 212 to experience higher amounts of stress that counteract the stress at the semiconductor device assembly.

In aspects, the stress characteristics of the semiconductor device assembly before the deposition of the dielectric material 302 can be determined based on testing (e.g., stress testing). In some cases, the testing is performed on the actual semiconductor device assembly at which the dielectric material 302 is to be deposited. Alternatively, the testing can be performed on another semiconductor device assembly having similar characteristics to the actual semiconductor device assembly at which the dielectric material 302 is to be deposited. Similarly, the stress properties of the dielectric material 302 can be determined based on testing. For example, the stress properties of various dielectric material deposited with various thicknesses through multiple techniques can be measured. After the stress properties have been measured, a particular dielectric material, a particular thickness deposited, or a particular technique that counteracts the stress experienced at the semiconductor device assembly can be selected for dielectric material 302.

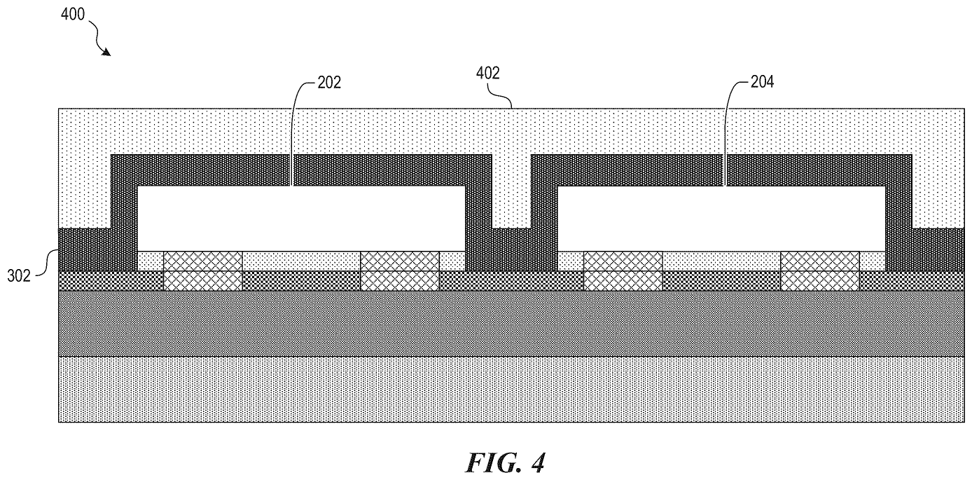

FIG. 4 illustrates a simplified schematic cross-sectional view of stage 400, where a dielectric material 402 is disposed at the dielectric material 302 and over the semiconductor die 202 and the semiconductor die 204. The dielectric material 402 can at least partially surround the semiconductor die 202 and the semiconductor die 204. Moreover, the dielectric material 402 can be disposed at least partially between the semiconductor die 202 and the semiconductor die 204. The dielectric material 402 can be disposed such that an upper surface of the dielectric material is flat. In aspects, the dielectric material 402 can be disposed through any appropriate technique, for example, chemical vapor deposition or physical vapor deposition.

Like the dielectric material 302, the dielectric material 402 can include a tensile dielectric or a compressive dielectric, which can be selected based on the stress characteristics of the semiconductor device assembly before the dielectric material 402 is disposed (e.g., after the dielectric material 302 is disposed). In some cases, the dielectric material 302 can include a tensile dielectric, and the dielectric material 402 can include a compressive dielectric. Alternatively, the dielectric material 302 can include a compressive dielectric, and the dielectric material 402 can include a tensile dielectric. In yet other cases, the dielectric material 302 and the dielectric material 402 can both include a tensile dielectric or a compressive dielectric. Moreover, like the dielectric material 302, other parameters of the dielectric material 402 can be selected based on the stress characteristics of the semiconductor device assembly. For example, a particular dielectric material, a particular thickness, or a particular deposition technique can be selected for the dielectric material 402 based on the stress characteristics of the semiconductor device assembly.

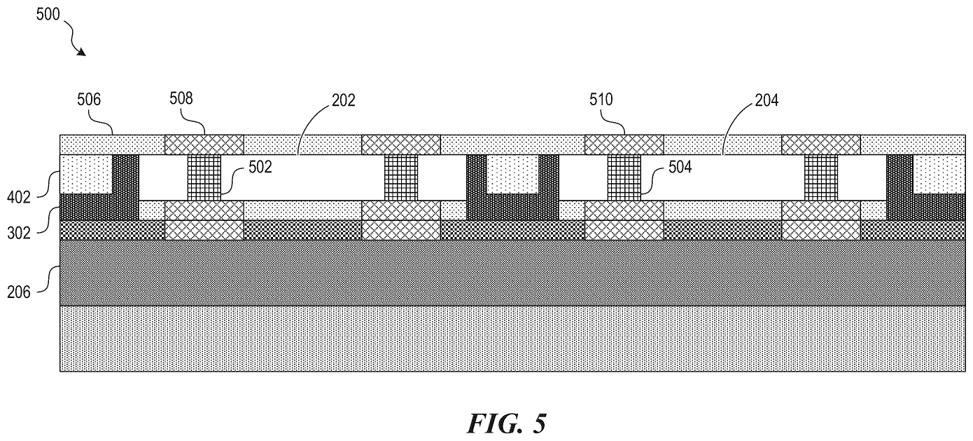

FIG. 5 illustrates a simplified schematic cross-sectional view of stage 500, at which a wafer is reconstructed from semiconductor die 202, semiconductor die 204, dielectric material 302, and dielectric material 402. The dielectric material 302 and the dielectric material 402 are thinned (e.g., through back grinding or chemical-mechanical planarization (CMP)) to expose the semiconductor die 202 and the semiconductor die 204. In aspects, the semiconductor die 202 or the semiconductor die 204 can be thinned. Given that the dielectric material 302 and the dielectric material 402 can reduce the stress in the semiconductor device assembly, the semiconductor die 202 or the semiconductor die 204 can be thinned to a greater extent while still limiting the risk of failure. For example, the semiconductor die 202 or the semiconductor die 204 can be thinned to a thickness less than 3 microns, 5 microns, 10 microns, and so on.

Moreover, the dielectric material 302 and the dielectric material 402 can fill the gaps on the wafer of semiconductor dies 206 outside the footprint of the semiconductor die 202 and the semiconductor die 204. Thus, after the semiconductor die 202 and the semiconductor die 204 are coupled with the wafer of semiconductor dies 206, the semiconductor device assembly can be reconstructed into a wafer using the dielectric material 302 and the dielectric material 402. As a result, the reconstructed wafer can be used for additional wafer-level processing. For example, holes can be created (e.g., drilled or etched) into the semiconductor die 202 and the semiconductor die 204, and TSVs 502 and TSVs 504 can be implemented in the openings in the semiconductor die 202 and the semiconductor die 204, respectively (e.g., a TSV-last process). In other cases, the thinning of the semiconductor die 202 and the semiconductor die 204 can expose the TSVs 502 and the TSVs 504 (e.g., a TSV-middle or TSV-first process).

A dielectric material 506 (e.g., a dielectric block) can be disposed at the back of the semiconductor die 202 and the semiconductor die 204. As illustrated, the dielectric material 506 can be disposed over the entire surface of the reconstructed wafer. For example, the dielectric material 506 can be disposed on the dielectric material 302 or the dielectric material 402. Contact pads 508 and contact pads 510 can be disposed on exposed portions of the TSVs 502 and the TSVs 504, respectively. The contact pads 508 and the contact pads 510 can be used to couple additional semiconductor dies to the semiconductor die 202 or the semiconductor die 204. For example, additional semiconductor dies can be stacked onto the reconstructed wafer, similar to the way in which the semiconductor die 202 and the semiconductor die 204 are coupled with the wafer of semiconductor dies 206. Given that the semiconductor device assembly can be a reconstructed wafer, additional dies stacked onto the semiconductor die 202 or the semiconductor die 204 can be assembled using wafer-level processes (e.g., chip-wafer bonding or wafer-wafer bonding). Thus, the additional processing steps (e.g., die bonding) can have the benefits of wafer-level processes, such as improved alignment and increased yield. Alternatively, additional semiconductor dies are not coupled with the semiconductor die 202 and the semiconductor die 204, and the contact pads 508 or the contact pads 510 can be used to test the semiconductor device assembly.

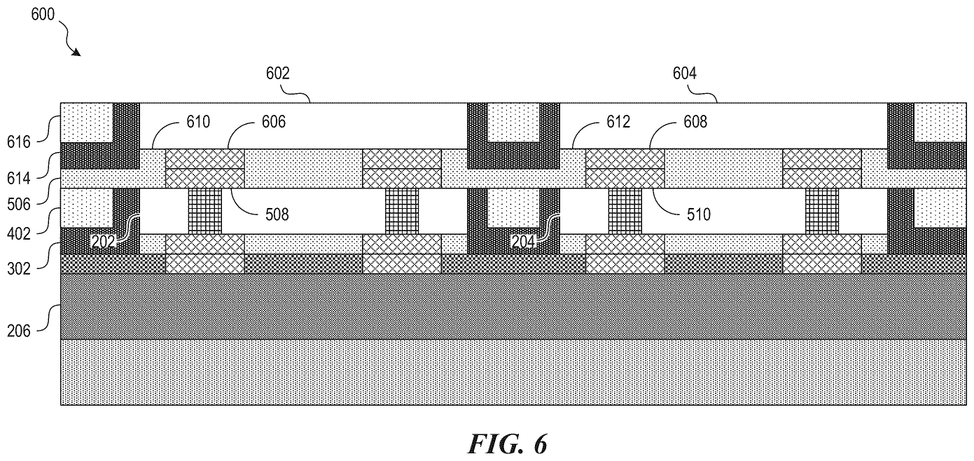

FIG. 6 illustrates a simplified schematic cross-sectional view of a semiconductor device assembly at stage 600, at which semiconductor die 602 and semiconductor die 604 are coupled (e.g., hybrid bonded) to the reconstructed wafer that includes the semiconductor die 202 and the semiconductor die 204. In general, the semiconductor die 602 and the semiconductor die 604 can be coupled to the reconstructed wafer in a similar manner to which the semiconductor die 202 and the semiconductor die 204 are coupled with the wafer of semiconductor dies 206. For example, the semiconductor die 602 can include contact pads 606 that couple with the contact pads 508 to form interconnects electrically coupling the semiconductor die 602 and the semiconductor die 202. Similarly, the semiconductor die 604 can include contact pads 608 that couple with contact pads 510 to form interconnects electrically coupling the semiconductor die 604 and the semiconductor die 204. Moreover, a dielectric material 610 (e.g., a dielectric block) and a dielectric material 612 (e.g., a dielectric block) at the semiconductor die 602 and the semiconductor die 604, respectively, can directly bond with the dielectric material 506.

Like the dielectric material 302 and the dielectric material 402, a dielectric material 614 and a dielectric material 616 can be disposed at the reconstructed wafer at least partially surrounding the semiconductor die 602 and the semiconductor die 604. Given that the dielectric material 506 can extend across the entire surface of the reconstructed wafer, the dielectric material 506 can separate the dielectric material 614 and the dielectric material 616 from the dielectric material 302 and the dielectric material 402. The dielectric material 614 and the dielectric material 616 can be disposed over the semiconductor die 602 and the semiconductor die 604 and thinned to expose the semiconductor dies. Thus, the semiconductor die 602, the semiconductor die 604, the dielectric material 614, and the dielectric material 616 can form an additional layer on a reconstructed wafer. In some cases, if the semiconductor die 602 and the semiconductor die 604 are the topmost dies, the dielectric material 614 or the dielectric material 616 can remain over the semiconductor die 602 and the semiconductor die 604. In aspects, the dielectric material 614 or the dielectric material 616 can be a tensile dielectric or a compressive dielectric based on the stress characteristics of the reconstructed wafer. Accordingly, stress in the semiconductor device assembly can be limited.

Similar to the semiconductor die 202 and the semiconductor die 204, the semiconductor die 602 or the semiconductor die 604 can include TSVs (not shown) to enable additional semiconductor dies to be stacked onto the semiconductor device assembly. Alternatively, the TSVs can provide a testing surface for probing the semiconductor device assembly. In yet other aspects, TSVs are not implemented in the semiconductor die 602 or the semiconductor die 604 because additional semiconductor dies are not stacked onto these dies.

Although illustrated in cross section such that only two semiconductor die stacks are shown, additional die stacks can be stacked onto the wafer of semiconductor dies 206. For example, the semiconductor device assembly can include 4, 8, 12, 30, 50, 100, or any other number of semiconductor die stacks. Similarly, although only two iterations of die stacking are illustrated, additional layers of semiconductor dies can be stacked onto the semiconductor device assembly by repeating the operations described with respect to FIGS. 5 and 6. Accordingly, the total number of semiconductor dies in each stack of semiconductor dies coupled to the wafer of semiconductor dies 206 can equal 2, 3, 4, 5, 6, 8, 10, 12, 14, 16, or any other number of semiconductor dies.

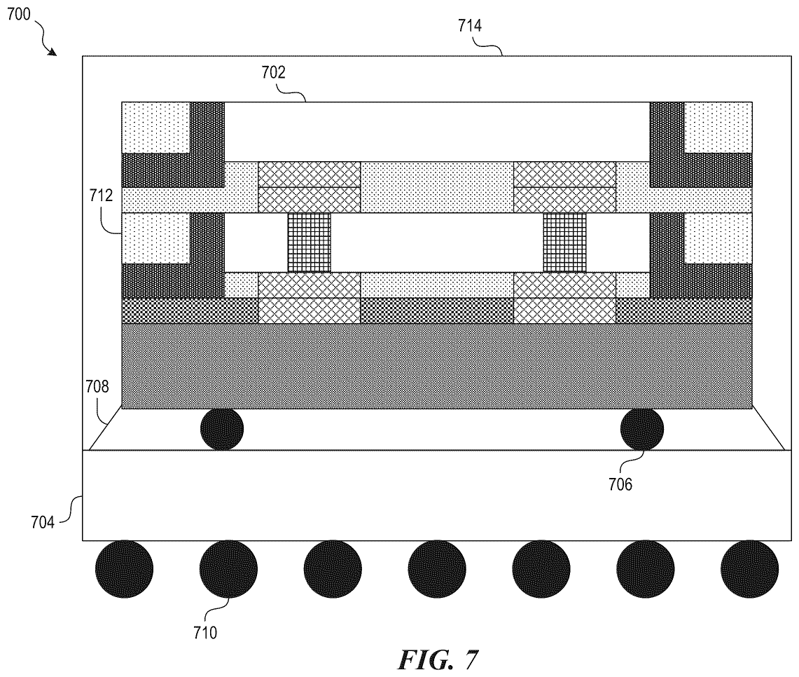

Once the various stacks of semiconductor dies are coupled to the wafer of semiconductor dies 206, the wafer of semiconductor dies 206 can be sawed to singulate the semiconductor device assembly into a plurality of semiconductor devices. For example, the semiconductor device assembly can be sawed through the wafer of semiconductor dies 206 and through the dielectric material between the various stacks of semiconductor dies. Each singulated semiconductor device can include one or more stacks of semiconductor dies. In aspects, the semiconductor device can be a high-bandwidth memory (HBM) device compliant with one or more HBM standard (e.g., HBM, HBM2, HBM3, and so on). In yet other aspects, each singulated semiconductor device can include a logic die (e.g., a central processing unit (CPU), graphics processing unit (GPU), processor, and so on) with multiple stacks of semiconductor dies (e.g., memory dies) mounted thereon at different lateral locations. Once singulated, the individual semiconductor devices can be packaged, as illustrated in FIG. 7.

FIG. 7 illustrates a simplified schematic cross-sectional view of a semiconductor device assembly at stage 700, where the stack of semiconductor dies 702 is packaged into a semiconductor device. With reference to FIG. 6, the stack of semiconductor dies 702 can include the semiconductor die 602, the semiconductor die 202, and a semiconductor die from the wafer of semiconductor dies 206. As illustrated, a base die of the stack of semiconductor dies 702 (e.g., the semiconductor die from the wafer of semiconductor dies 206) can have a larger footprint than the other dies in the stack of semiconductor dies 702. The base die of the stack of semiconductor dies 702 can be coupled with a package-level substrate 704 (e.g., printed-circuit board (PCB), interposer, etc.). Connective structures 706 (e.g., solder balls, solder bumps, conductive pillars, etc.) may be disposed between contact pads (not shown) at the base die and contact pads (not shown) at a top side of the package-level substrate 704 to implement interconnects that electrically couple the stack of semiconductor dies 702 and the package-level substrate 704.

An underfill material 708 (e.g., capillary underfill) can be provided between the stack of semiconductor dies 702 and the package-level substrate 704 to provide electrical insulation to the connective structures 706 and structurally support the assembly. The package-level substrate 704 can include internal routing circuitry (e.g., traces, lines, vias, and other connective structures) that connects the contact pads at the top surface to contact pads (not shown) at the bottom side. Connective structures 710 can be disposed at the contact pads at the bottom side to provide external connectivity to other devices (e.g., on a motherboard).

The semiconductor device assembly may include dielectric sidewalls 712 as a result of sawing through the dielectric material disposed at the wafer of semiconductor dies 206, as illustrated in FIG. 6. The sidewalls 712 extend from the base semiconductor die 602 and up to a topmost die of the stack of semiconductor dies 702. As such, the sidewalls 712 can at least partially surround the stack of semiconductor dies 702. As illustrated, the sidewalls 712 do not extend over the stack of semiconductor dies 702, for example, because the dielectric material 614 and the dielectric material 616 of FIG. 6 have been thinned or planarized down to expose the stack of semiconductor dies 702. In other implementations, however, the sidewalls 712 may extend over the top of the stack of semiconductor dies 702. The semiconductor device assembly can further include an encapsulant material 714 (e.g., mold resin compound or the like) that at least partially encapsulates the stack of semiconductor dies 702 and the package-level substrate 704 to prevent electrical contact therewith and provide mechanical strength and protection to the assembly.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-7 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

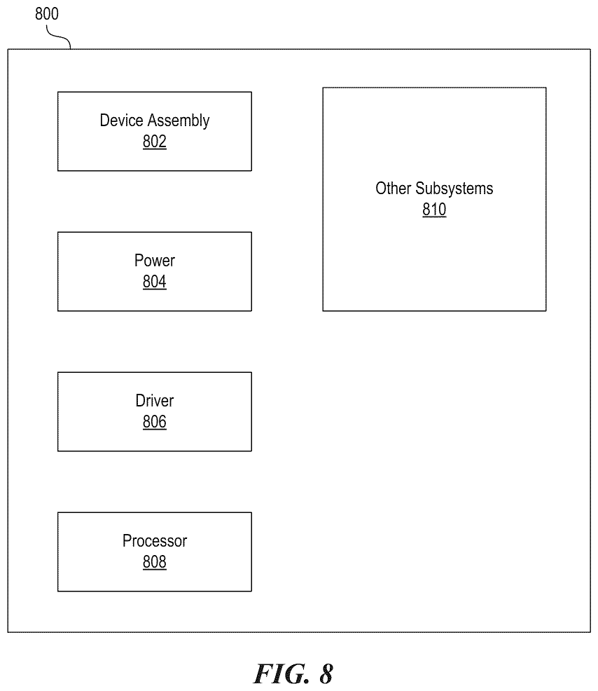

Any one of the semiconductor devices and semiconductor device assemblies described above with reference to FIGS. 1-7 can be incorporated into any of a myriad of larger and/or more complex systems, a representative example of which is system 800 shown schematically in FIG. 8. The system 800 can include a semiconductor device assembly 802 (e.g., a discrete semiconductor device), a power source 804, a driver 806, a processor 808, and/or other subsystems or components 810. The semiconductor device assembly 802 can include features generally similar to those of the semiconductor device assemblies described above with reference to FIGS. 1-7. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances and other products. Components of the system 800 may be housed in a single unit or distributed over multiple, interconnected units (e.g., through a communications network). The components of the system 800 can also include remote devices and any of a wide variety of computer-readable media.

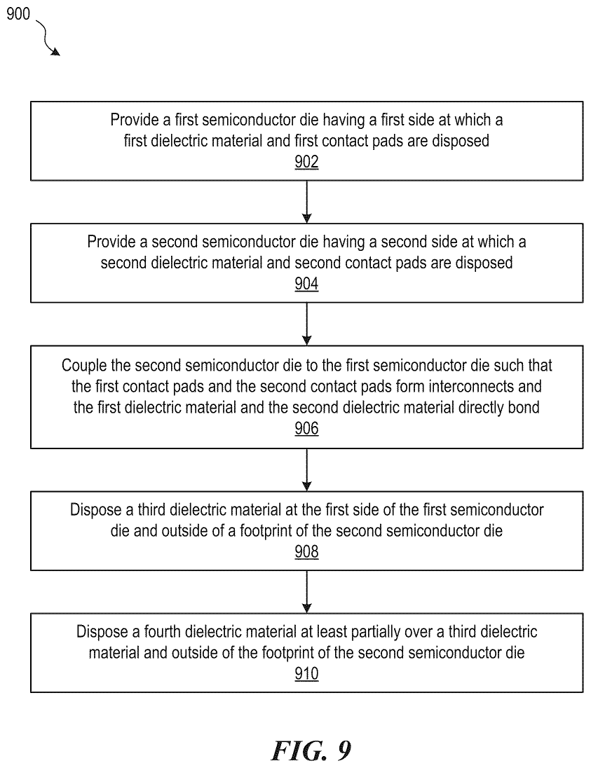

FIG. 9 illustrates an example method 900 for fabricating a semiconductor device assembly in accordance with an embodiment of the present technology. Although illustrated in a particular configuration, one or more operations of the method 900 may be omitted, repeated, or reorganized. Additionally, the method 900 may include other operations not illustrated in FIG. 9, for example, operations detailed in one or more other methods described herein.

At 902, a first semiconductor die is disposed. The first semiconductor die has a first side at which a first dielectric material and first contact pads are disposed. At 904, a second semiconductor die is provided. The second semiconductor die has a second side at which a second dielectric material and second contact pads are disposed. At 906, the second semiconductor die is coupled to the first semiconductor die such that the first contact pads and the second contact pads form interconnects and the first dielectric material and the second dielectric material directly bond. At 908, a third dielectric material is disposed at the first side of the first semiconductor die and beyond a footprint of the second semiconductor die. The third dielectric material can include a first one of a tensile dielectric material configured to experience tensile stress at a first upper surface and compressive stress at a first lower surface, and a compressive dielectric material configured to experience compressive stress at a second upper surface and tensile stress at a second lower surface. At 910, a fourth dielectric material is disposed at least partially over the third dielectric material and outside of the footprint of the second semiconductor die. The fourth dielectric material can include the other of the tensile dielectric material and the compressive dielectric material.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die having a first side at which a first dielectric material and first contact pads are disposed; and
a second semiconductor die having:
a second side at which a second dielectric material and second contact pads are disposed; and
a third side opposite the second side,
wherein the second semiconductor die is coupled with the first semiconductor die such that the first contact pads and the second contact pads form interconnects electrically coupling the first semiconductor die and the second semiconductor die and the first dielectric material and the second dielectric material are directly bonded;
a third dielectric material disposed at the first side of the first semiconductor die and beyond a footprint of the second semiconductor die; and
a fourth dielectric material disposed at least partially over the third dielectric material and outside of the footprint of the second semiconductor die,
wherein the third dielectric material comprises one of:
a tensile dielectric material configured to experience tensile stress at a first upper surface and compressive stress at a first lower surface; and
a compressive dielectric material configured to experience compressive stress at a second upper surface and tensile stress at a second lower surface, and
wherein the fourth dielectric material comprises the other of:
the tensile dielectric material; and
the compressive dielectric material.

2. The semiconductor device assembly of claim 1, wherein the third dielectric material extends at least partially up an edge of the second semiconductor die between the second side and the third side.

3. The semiconductor device assembly of claim 1, wherein the third dielectric material comprises silicon oxide.

4. The semiconductor device assembly of claim 1, wherein the fourth dielectric material comprises silicon nitride.

5. The semiconductor device assembly of claim 1, wherein:
a fifth dielectric material disposed at the third side; and
the third dielectric material contacts the fifth dielectric material.

6. The semiconductor device assembly of claim 1, wherein:
the second semiconductor die further comprises:
through-silicon vias (TSVs) extending from the second side to the third side;
third contact pads disposed at the third side on the TSVs; and
a fifth dielectric material disposed at the third side; and
the semiconductor device assembly further comprises:
a third semiconductor die having:
a fourth side at which a sixth dielectric material and fourth contact pads are disposed; and
a fifth side opposite the fourth side,
wherein the third semiconductor die is coupled with the second semiconductor die such that the third contact pads and the fourth contact pads form second interconnects electrically coupling the second semiconductor die and the third semiconductor die and the fifth dielectric material and the sixth dielectric material are directly bonded;
a seventh dielectric material disposed above the fourth dielectric material,
wherein the seventh dielectric material comprises one of:
an additional tensile dielectric material; and
an additional compressive dielectric material; and
an eighth dielectric material disposed above the fourth dielectric material,
wherein the eighth dielectric material comprises the other of:
the additional tensile dielectric material; and
the additional compressive dielectric material.

7. The semiconductor device assembly of claim 6, wherein the fifth dielectric material is disposed at least partially over the fourth dielectric material such that the fifth dielectric material is disposed at least partially between the fourth dielectric material and the seventh dielectric material.

8. The semiconductor device assembly of claim 1, wherein a thickness of the third dielectric material is different from a thickness of the fourth dielectric material.

9. A method for fabricating a semiconductor device assembly, comprising:
providing a first semiconductor die having a first side at which a first dielectric material and first contact pads are disposed;
providing a second semiconductor die having a second side at which a second dielectric material and second contact pads are disposed;
coupling the second semiconductor die to the first semiconductor die such that the first contact pads and the second contact pads form interconnects and the first dielectric material and the second dielectric material directly bond;
disposing a third dielectric material at the first side of the first semiconductor die and beyond a footprint of the second semiconductor die; and
disposing a fourth dielectric material at least partially over the third dielectric material and outside of the footprint of the second semiconductor die,
wherein the third dielectric material comprises one of:
a tensile dielectric material configured to experience tensile stress at a first upper surface and compressive stress at a first lower surface; and
a compressive dielectric material configured to experience compressive stress at a second upper surface and tensile stress at a second lower surface, and
wherein the fourth dielectric material comprises the other of:
the tensile dielectric material; and
the compressive dielectric material.

10. The method of claim 9, further comprising:
disposing the third dielectric material and the fourth dielectric material at least partially over a third side of the second semiconductor die; and
thinning the third dielectric material and the fourth dielectric material to expose the third side of the second semiconductor die.

11. The method of claim 9, further comprising disposing the third dielectric material along an edge of the second semiconductor die.

12. The method of claim 9, wherein the first semiconductor die is included in a wafer of semiconductor dies that further includes a third semiconductor die, the method further comprising:
coupling a fourth semiconductor die to the third semiconductor die; and
disposing the third dielectric material and the fourth dielectric material at a first side of the wafer of semiconductor dies between the second semiconductor die and the fourth semiconductor die.

13. The method of claim 12, further comprising:
disposing a fifth dielectric material at least partially over the second semiconductor die, the fourth semiconductor die, and the fourth dielectric material; and
coupling a fifth semiconductor die to the second semiconductor die through the fifth dielectric material.

14. The method of claim 9, further comprising, after disposing the third dielectric material and the fourth dielectric material, disposing through-silicon vias in the second semiconductor die.

15. The method of claim 9, further comprising:
determining that the first side of the first semiconductor die is configured to experience tensile stress; and
selecting the tensile dielectric material as the third dielectric material based on the first side of the first semiconductor die being configured to experience tensile stress.

16. The method of claim 9, further comprising:
determining that the first side of the first semiconductor die is configured to experience compressive stress; and
selecting the compressive dielectric material as the third dielectric material based on the first side of the first semiconductor die being configured to experience compressive stress.

17. The method of claim 9, further comprising:
determining that the first semiconductor die is configured to experience a particular amount of stress; and
disposing the third dielectric material with a particular thickness or deposition technique based on the particular amount of stress.

18. A semiconductor device assembly, comprising:
a first semiconductor die;
a second semiconductor die hybrid bonded with the first semiconductor die such that metal-metal interconnects electrically couple the first semiconductor die and the second semiconductor die; and
a dielectric sidewall disposed at the first semiconductor die and at least partially surrounding the second semiconductor die, the dielectric sidewall comprising:
a tensile dielectric material configured to experience tensile stress at a first upper surface and compressive stress at a first lower surface; and
a compressive dielectric material configured to experience compressive stress at a second upper surface and tensile stress at a second lower surface.

19. The semiconductor device assembly of claim 18, wherein a ratio of the tensile dielectric material to the compressive dielectric material is between 1:2 and 2:1.

20. The semiconductor device assembly of claim 18, wherein:
the first semiconductor die comprises a logic die; and
the second semiconductor die comprises a memory die.
